(19) United States
(12) Patent Application Publication
(10) Pub. No.: US 2015/0311240 A1
(43) Pub. Date: Oct. 29, 2015

(54) DEEP WELL PHOTODIODE FOR NIR IMAGE SENSOR

(71) Applicants: Sony Corporation, Tokyo (JP); Pixim, Inc., Mountain View, CA (US)

(72) Inventors: Muriel Cohen, Mountain View, CA (US); Fred Brady, Webster, NY (US); Thomas R. Ayers, Morgan Hill, CA (US); Sungin Hwang, Pittsford, NY (US)

(73) Assignee: Sony Corporation, Tokyo (JP)

(21) Appl. No.: 14/263,630

(22) Filed: Apr. 28, 2014

(51) Int. Cl. H01L 27/146; H04N 5/378

(52) U.S. Cl. CPC H01L 27/1464; H01L 27/1461; H01L 27/14607; H01L 27/14649; H01L 27/14689; H01L 27/14612; H04N 5/378

(57) ABSTRACT

An active pixel image sensor includes a photodiode structure which enables high near-infrared modulation transfer function and high quantum efficiency, with low pinning voltage for a medium- to large-size pixel. The photodiode includes a shallow photodiode region and a deep photodiode region both of a first dopant type, where the length of the shallow photodiode region is larger than the length of the deep photodiode region; and a shallow depleting region and a deep depleting region both of a second dopant type. The deep depleting region surrounds the deep photodiode region on at least two opposite sides.

### BACKGROUND

1. Technical Field

This disclosure relates generally to digital image sensors and, more specifically, to image sensors having good sensitivity in the near-infrared (NIR) spectral regions.

2. Description of Related Art

Solid-state image sensors work by converting incident photons into electron-hole pairs. An image sensor typically includes a two-dimensional array of light sensing elements called “pixels.” Either the electron or hole is then collected by the sensor and converted into an output signal for each pixel or group of pixels. The depth at which the photon conversion occurs depends on the absorption coefficient of the detector material. The absorption coefficient varies by material, but decreases with longer wavelengths for a given material. As the absorption coefficient decreases, light penetrates more deeply into the detector material.

Photodetectors based on silicon are typically sensitive to light in the 350-1100 nm wavelength range, where short-wavelength light is detected near the silicon surface and long-wavelength light can pass through thicker silicon without generating an electron-hole pair. For example, at 850 nm (a wavelength in the NIR spectral region), the absorption depth for a silicon-based photodetector is around 12 μm.

Silicon-based image sensor designs include Charge-Coupled Devices (CCD), Complementary Metal-Oxide-Semiconductor (CMOS) image sensors, and the like. CMOS image sensors have the advantages of lower power consumption, and include built-in analog-to-digital converters that provide digital output pixel values.

A basic CMOS image sensor pixel consists of a photodetector such as a photodiode, readout transistors, a floating diffusion (FD), and an output node. A key aspect of pixel operation in a CMOS image sensor is the photodiode pinning voltage Vₚᵢₙ. Typically, a photodiode is designed so that it becomes depleted throughout its thickness at a predetermined voltage. This voltage at which the photodiode becomes fully depleted is known as its pinning voltage. To achieve full depletion, the photodiode is sandwiched between a shallow, highly doped region of opposite doping type, and an epitaxial region which is also of the opposite doping type. The pinning voltage can be increased by increasing the doping concentration in the photodiode, by making the photodiode thicker, or by decreasing the dopant concentration of the shallow surface implant. Increasing Vₚᵢₙ typically increases the charge that can be collected by the photodiode, and so increases the dynamic range of the pixel.

However, the floating diffusion must hold all of the charge collected by the photodiode, and so the floating diffusion charge capacity should be slightly larger than the capacity of the photodiode. The charge capacity of the floating diffusion is proportional to its maximum voltage swing. The voltage on the floating diffusion must remain slightly higher than the minimum photodiode potential, so the maximum floating diffusion voltage swing is roughly given by its reset voltage minus the photodiode Vₚᵢₙ. Therefore, there is a maximum Vₚᵢₙ above which the pixel signal no longer increases, but lag problems continue to increase. Additionally, increasing Vₚᵢₙ typically leads to an increase in dark current as well as hot defective pixels.

To capture deeply penetrating NIR light, CMOS sensors need deep charge collection regions. However, because CMOS sensors are generally fabricated using typical CMOS processing steps, the photodiode regions tend to be shallow. This means that the generated carriers must travel a long distance to the photodiode, which may result in an increase in pixel cross-talk and a decrease in quantum efficiency (QE) and modulation transfer function (MTF). To improve MTF, the photodiode may be implanted deeper. However, as explained above, increasing the photodiode thickness makes Vₚᵢₙ too high, causing the photodiode to not function correctly.

Accordingly, there is a need for an image sensor and photodiode wherein Vₚᵢₙ is kept as low as possible while still meeting dynamic range needs.

### SUMMARY

The present disclosure is directed to a photodiode, image sensing device, and electronic apparatus. In one aspect of the present disclosure, an image sensing device comprises a photodiode region of a first dopant type, the photodiode region including a shallow photodiode region and a first deep photodiode region, wherein a length of the shallow photodiode region is larger than a length of the first deep photodiode region; a depleting region of a second dopant type, the depleting region including a shallow depleting region and a deep depleting region, wherein the deep depleting region surrounds the first deep photodiode region on at least two opposite sides; and an epitaxial layer, wherein the second dopant type is of opposite dopant type to the first dopant type.

In another aspect of the present disclosure, the photodiode region further includes a second deep photodiode region, wherein a length of the second deep photodiode region is larger than the length of the first deep photodiode region.

In another aspect of the present disclosure, a method of manufacturing an image sensing device comprises forming a photodiode region of a first dopant type, the photodiode region including a shallow photodiode region and a first deep photodiode region, wherein a length of the shallow photodiode region is larger than a length of the first deep photodiode region; forming a depleting region of a second dopant type, the depleting region including a shallow depleting region and a deep depleting region, wherein the deep depleting region surrounds the first deep photodiode region on at least two opposite sides; and forming an epitaxial layer, wherein the second dopant type is of opposite dopant type to the first dopant type.

The present disclosure may be better understood upon consideration of the detailed description below and the accompanying figures.

### BRIEF DESCRIPTION OF THE DRAWINGS

FIG. 1 is an exemplary image sensor for use with aspects of the present disclosure.

FIG. 2 is an exemplary image sensor for use with aspects of the present disclosure.

FIG. 3 is an exemplary pixel circuit for use with aspects of the present disclosure.

FIG. 4 is a cross-section of a comparative photodiode.

FIG. 5 is a cross-section of an exemplary photodiode according to aspects of the present disclosure.

FIG. 6 is a cross-section of another exemplary photodiode according to aspects of the present disclosure.

FIG. 7 is a cross-section of yet another exemplary photodiode according to aspects of the present disclosure.

FIG. 8 is a cross-section of yet another exemplary photodiode according to aspects of the present disclosure.

FIG. 9 is a process flow according to aspects of the present disclosure.

FIG. 10 is an exemplary electronic apparatus according to aspects of the present disclosure.

### DETAILED DESCRIPTION

[Image Sensing Device—General Configuration]

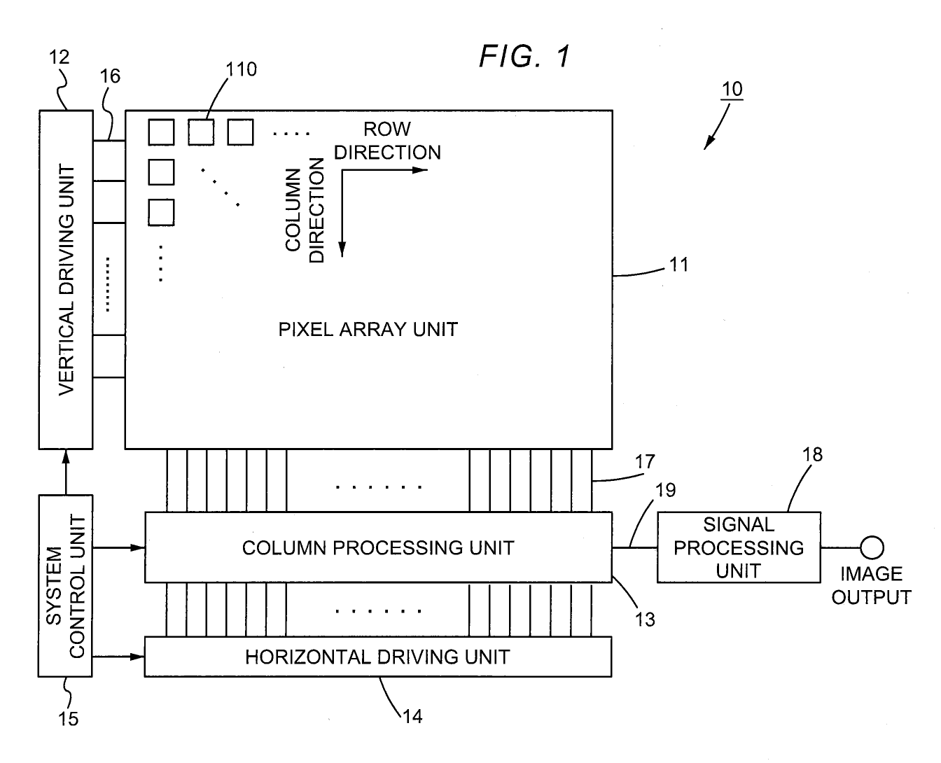

FIG. 1 illustrates an exemplary image sensor 10. Image sensor 10 is formed on a semiconductor substrate; for example, a silicon substrate as will be described in more detail below. Image sensor 10 includes a pixel array unit 11 in which a plurality of pixels 110 are arranged, for example, in an n×m matrix having n rows and m columns. The pixel array unit 11 may include an effective pixel region and an optical black pixel region (not illustrated). Pixels 110 in the effective region are configured to output a pixel signal which corresponds to the bits (also called dots or pixels) of an image created by the image sensor. Pixels in the optical black region, on the other hand, are configured to output black level signals used as a reference for various noise cancellation techniques. Pixels in the optical black region are structurally identical to pixels 110 in the effective pixel region, except that they are shielded from incident light. The optical black region is preferably located at the periphery of the effective pixel region along one or more edges of the pixel array unit 11. The pixel array unit 11 may also include dummy pixels configured to perform various functions but which do not correspond to bits in the output image. Hereinafter, the term “pixel 110” refers to a pixel for outputting pixel signals which correspond to the bits of an image created by the image sensor, unless explicitly indicated otherwise. Each pixel 110 comprises a photodiode as a light receiving element having a photoelectric conversion function, and MOS transistors, as will be described in more detail below.

The image sensor includes various driving sections preferably arranged around the periphery of the pixel array unit 11. These driving sections control the operations of the image sensor, and may be collectively referred to as a “control section” when differentiation between individual components thereof is not necessary. The operations of the pixels 110 are controlled by a vertical driving unit 12, which is configured to apply signals to control lines 16 that are connected to respective rows of pixels. The vertical driving unit 12 may include address decoders, shift registers, and the like, as is familiar in the art, for generating control pulses. An operation of reading out signals from the pixels 110 is performed via a column processing unit 13, which is connected to respective columns of pixels via column readout lines 17. A horizontal driving unit 14 controls the readout operations of the column processing unit 13, and may include shift registers and the like, as is familiar in the art. A system control unit 15 is provided to control the vertical driving unit 12, the column processing unit 13, and the horizontal driving unit 14 by, for example, generating various clocks and control pulses. The signals read out by the column processing circuit 13 are output via a horizontal output line 19 to a signal processing unit 18 which is configured to receive signals, perform various signal processing functions, and output image data.

The general configuration described above is merely an example, and it will be understood that alternative configurations could also be implemented. For example, the signal processing unit 18 and/or a storage unit (not illustrated) could be configured in a column-parallel manner similarly to the column processing unit 13, such that the pixels signals from respective columns undergo signal processing in parallel. As another example, the signal processing unit 18 and/or a storage unit (not illustrated) can be included in the same integrated circuit as the pixel array unit 11, or may be provided in a separate circuit not integrated with the pixel array unit 11.

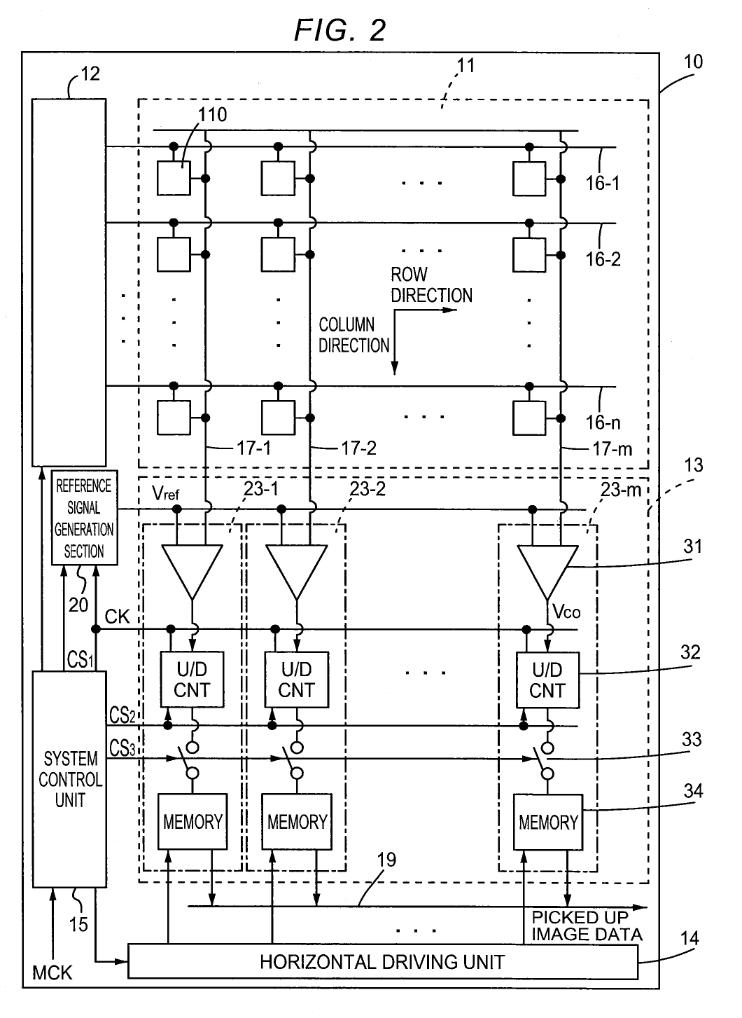

FIG. 2 illustrates the image sensor of FIG. 1 in more detail. As shown in FIG. 2, the column processing unit 13 preferably includes an analog-to-digital (“A/D”) converter 23-1, 23-2, . . . , 23-m for each column 1, 2, . . . , m. Hereinafter, the term “A/D converter 23” will be used when it is not necessary to distinguish between the individual A/D converters in respective columns. By the A/D converters 23, A/D conversion is performed in a column-parallel manner as pixel signals are read out one row at a time. In particular, the vertical driving unit 12 selects one row at a time for readout, and each respective pixel 110 in the selected row outputs a signal to respective column readout line 17 to which it is connected. The A/D converters 23 for each column perform A/D conversion on the signals in parallel. Thereafter, the horizontal driving unit 14 causes the A/D converters 23 to output the digital signals to the horizontal output line 19 serially (that is, one at a time).

The A/D converter 23 preferably includes a comparator 31, a counter 32, a switch 33, and a memory (latch) 34. Comparator 31 has one input connected to a respective column readout line 17, and the other input connected to a reference voltage V_{ref} generated by a reference signal generation section 20. Although reference signal generation section 20 is illustrated as being separate from system control unit 15, reference signal generation section 20 may be integrated with system control unit 15. The output of comparator 31 is connected to counter 32, whose output is in turn connected via switch 33 to memory 34. During a readout operation, the reference signal generation section 20 causes the voltage V_{ref}, beginning at an initial time t₀, to take the form of a ramp voltage which changes magnitude approximately linearly with time at a set rate. Counter 32 starts counting at time t₀, and when the voltage V_{ref} becomes equal to the potential carried on column readout line 17 (for example, at a time t₁), comparator 31 inverts its output causing the counter to stop counting. The count of counter 23 therefore corresponds to the amount of time between time t₀ (when V_{ref} starts to change magnitude) and time t₁ (when V_{ref} becomes equal to the potential of column readout line 17). Because the rate of change of V_{ref} is known, the time between t₀ and t₁ corresponds to the magnitude of the potential of column readout line 17. Thus, the analog potential of column readout line 17 is converted into a digital value which is output by the counter 23. The digital value is output by counter 23 via switch 33 to memory 34, where the digital value is held until horizontal driving unit 14 causes the memory to output the value via horizontal output line 19. A correlated double sampling (CDS) technique may be employed, in which a reset level is subtracted from a pixel signal, so as to cancel out any variations between reset levels across pixels and time.

System control unit 15 may preferably generate clock signals and control signals for controlling various other sections, such as a clock signal CK and control signals CS1, CS2, and CS3, based on a master clock signal MCK input into system control unit 15. Master clock signal MCK may be, for example, an input from a circuit other than the integrated circuit in which pixel array unit 11 is included; for example, from a processor of a device in which the image sensor is installed.

Control lines 16 and column readout lines 17 are preferably formed in multiple wiring layers that are laminated on top of one another with inter-layer insulating films therebetween. The wiring layers are preferably formed on top of the pixels on a front-face side of the semiconductor substrate for front-side illuminated pixels, and on a back-side face of the semiconductor substrate for back-side illuminated pixels.

[Pixel Circuit—General Configuration and Operation]

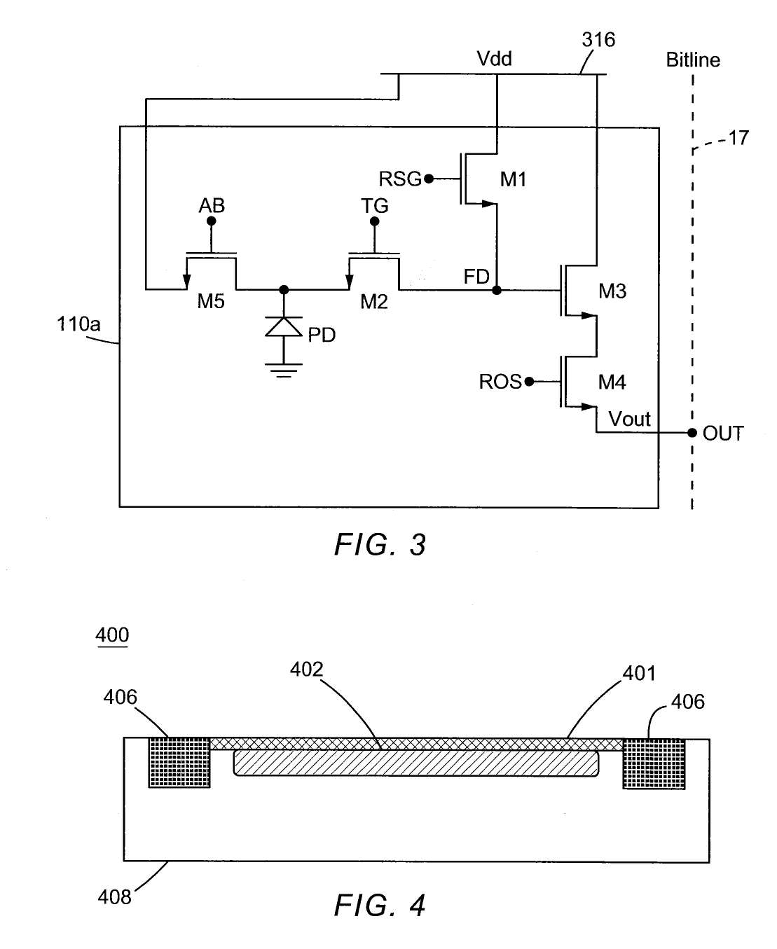

FIG. 3 illustrates an exemplary CMOS image sensor pixel 110a. FIG. 3 illustrates a so-called 5T (five transistor) pixel; however, the present disclosure is not particularly limited in this regard. For example, an exemplary CMOS image sensor pixel may include more or fewer transistors, such as 3T, 4T, or 6T configurations. Furthermore, other active or passive circuit elements may be included in a pixel according to the present disclosure, including capacitors and/or resistors. Additionally, although not illustrated in FIG. 3, various transistors may be shared between adjacent pixels.

The particular CMOS image sensor pixel 110a, illustrated in FIG. 3, comprises a photodiode PD, several readout transistors M1-M5, a floating diffusion FD, and an output node OUT. The exemplary pixel operation begins with a photodiode-and-floating-diffusion reset operation. In this operation, the reset transistor M1 and the transfer transistor M2 turn on by setting a reset signal RSG and a transfer signal TG high, respectively, which sets the floating diffusion FD to a power supply voltage V_{dd} and the photodiode to a pinning voltage Vₚᵢₙ, as described above. When the reset transistor M1 and transfer transistor M2 turn off by setting reset signal RSG and transfer signal TG low, respectively, the reset operation is complete and an exposure time starts. At the end of the exposure time, the transfer transistor M2 turns on by again setting the transfer signal TG high, which transfers charge accumulated in the photodiode to the floating diffusion FD. The voltage on floating diffusion FD controls the gate voltage on a source-follower transistor M3. Pixel output is enabled by setting a row select signal ROS high so as to turn on a row select transistor M4. When the row select transistor is so set, the output voltage Vₒᵤₜ is controlled according to the voltage on the source-follower transistor and, ultimately, the floating diffusion voltage.

In the exemplary 5T configuration illustrated here, a photodiode-only reset operation may be accomplished simply by setting a global shutter signal AB high and thereby causing a global shutter transistor M5 to be turned on. This is in contrast to the photodiode-and-floating-diffusion reset operation described above, which requires turning on both the reset transistor M1 and the transfer transistor M2 together. The photodiode-only reset operation allows for the photodiode PD to be affirmatively reset without affecting a charge held on the floating diffusion FD.

[Photodiode Structure—Comparative Example]

As noted above, the pixels 110 of the present disclosure include, regardless of their general configuration, a photodiode that is configured to convert incident light into electrical signals. Various advantages of aspects of the present disclosure are related to the structure of the photodiode. In order to aid an understanding of these advantages, a comparative example will first be considered in which the photodiode has a different structure from that of aspects of the present disclosure.

FIG. 4 illustrates a structure of a comparative photodiode 400. In the comparative example, photodiode 400 comprises a substrate 408 including a shallow p-type photodiode implant 401 at the surface thereof and a shallow n-type photodiode implant 402 at a shallow location beneath the surface thereof. The photodiode implants are isolated from adjacent elements by shallow trench implants (STI) 406.

[Photodiode Structure—Exemplary Embodiments]

In accordance with the principles of the present disclosure, an active pixel CMOS image sensor implements a photodiode exhibiting improved long wavelength performance. Exemplary photodiodes include a shallow photodiode region and a deep photodiode region. All regions of the exemplary photodiode are fully depleted of carriers during a photodiode reset operation; that is, no neutral regions remain.

The exemplary photodiodes preferably include a shallow wide photodiode region of medium dose, and a deep narrow stripe photodiode region of lower dose, the photodiode regions having a first (that is, p or n) dopant type. Exemplary photodiodes also include a shallow high dose depleting region of opposite dopant type that depletes the top of the photodiode, and a deep low dose depleting region of opposite dopant type that depletes the side of the stripe. The deep photodiode region is connected to the shallow photodiode region in order to facilitate the collection of deeply generated carriers.

The deep depleting region is formed at approximately the same depth as the deep photodiode region, and surrounds the deep photodiode region on at least two sides. The deep depleting region is preferably done at a higher dose than the deep photodiode region in order to facilitate depletion of the deep photodiode region. The deep depleting region is placed deep enough below the shallow photodiode region to prevent it from undesirably compensating the shallow photodiode region and thereby degrading its charge collection efficiency.

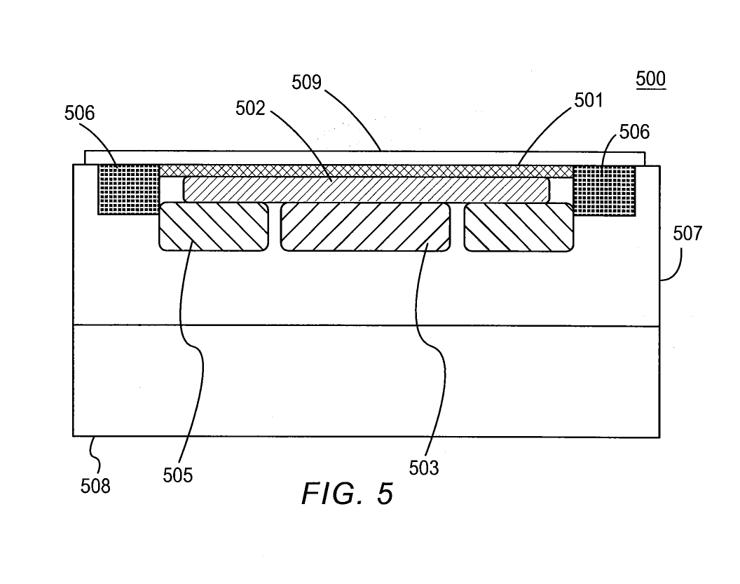

FIG. 5 illustrates a structure of an exemplary photodiode 500 according to an aspect of the present disclosure. Photodiode 500 has a “T-well” structure comprising a shallow depleting implant 501, a shallow photodiode implant 502, a deep photodiode implant 503, and deep depleting implants 505. The photodiode implants are isolated from adjacent elements by STIs 506. Photodiode implants 501-503 and 505 may be formed in an epitaxial layer 507 and/or may be formed on a substrate 508. Furthermore, photodiode 500 may include a gate oxide layer 509. As illustrated by FIG. 5, the shallow photodiode implant 502 and deep photodiode implant 503 are connected to form a “T” shape where the top and arms of the “T” are formed by shallow photodiode implant 502 and the leg of the “T” is formed by deep photodiode implant 503.

As seen in FIG. 5, the shallow depleting implant 501 extends across the width of the photodiode 500, and the shallow photodiode implant 502 extends across most of the width of the photodiode 500. The deep photodiode implant 503 has a reduced width compared to the shallow photodiode implant 502, and is enclosed on at least two opposite sides by the deep depleting implant 505. In other words, a length of the shallow photodiode implant 502 is larger than a length of the deep photodiode implant 503. The deep photodiode implant 503 has substantially the same depth as the deep depleting implant 505.

In photodiode 500, photodiode implants 502, 503 are formed of a first dopant type, and depleting implants 501, 505 are formed of a second dopant type. In order to provide a p-n junction, the first and second dopant types are of opposite dopant type to one another.

FIG. 6 illustrates an exemplary photodiode 600 according to another aspect of the present disclosure. Photodiode 600 has an “H-well” structure comprising a shallow depleting implant 601, a shallow photodiode implant 602, a first deep photodiode implant 603, a second deep photodiode implant 604, and deep depleting implants 605. The photodiode implants are isolated from adjacent elements by STIs 606. Photodiode implants 601-605 may be formed in an epitaxial layer 607 and/or may be formed on a substrate 608. Furthermore, photodiode 600 may include a gate oxide layer 609. As illustrated by FIG. 6, the shallow photodiode implant 602, first deep photodiode implant 603, and second deep implant 604 are connected to form a sideways “H” shape where the top and bottom arms of the “H” are formed by shallow photodiode implant 602 and second deep photodiode implant 604, respectively, and the middle connector of the “H” is formed by first deep photodiode implant 603.

As seen in FIG. 6, the shallow depleting implant 601 extends across the width of the photodiode 600, and the shallow photodiode implant 602 extends across most of the width of the photodiode 600. The first deep photodiode implant 603 has a reduced width and is enclosed on at least two opposite sides by the deep depleting implant 605. In other words, a length of the shallow photodiode implant 602 is larger than a length of the first deep photodiode implant 603. The first deep photodiode implant 603 has substantially the same depth as the deep depleting implant 605. Furthermore, the second deep photodiode implant 604 has an increased width compared to the first deep photodiode implant 603. In other words, a length of the second deep photodiode region 604 is larger than the length of the first deep photodiode region 603, and may preferably be equal to the length of the shallow photodiode region 602. The second deep photodiode region 604 is deeper than the deep depleting region 605. The second deep photodiode region 604 is sufficiently thin and of sufficiently low doping to be fully depleted of carriers during a standard voltage reset of the photodiode 600.

In photodiode 600, photodiode implants 602-604 are formed of a first dopant type, and depleting implants 601, 605 are formed of a second dopant type. In order to provide a p-n junction, the first and second dopant types are of opposite dopant type to one another.

While photodiode6700 may require more process complexity during formation thereof to achieve a sufficiently low pinning voltage, the wide area of the photodiode regions provide an improvement in QE and MTF.

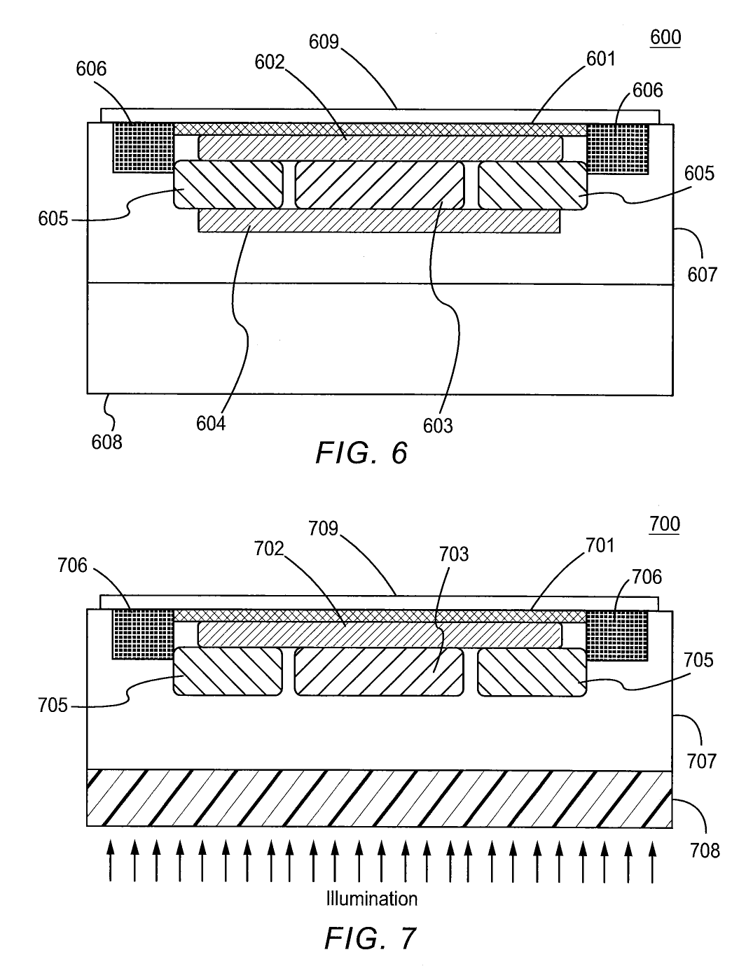

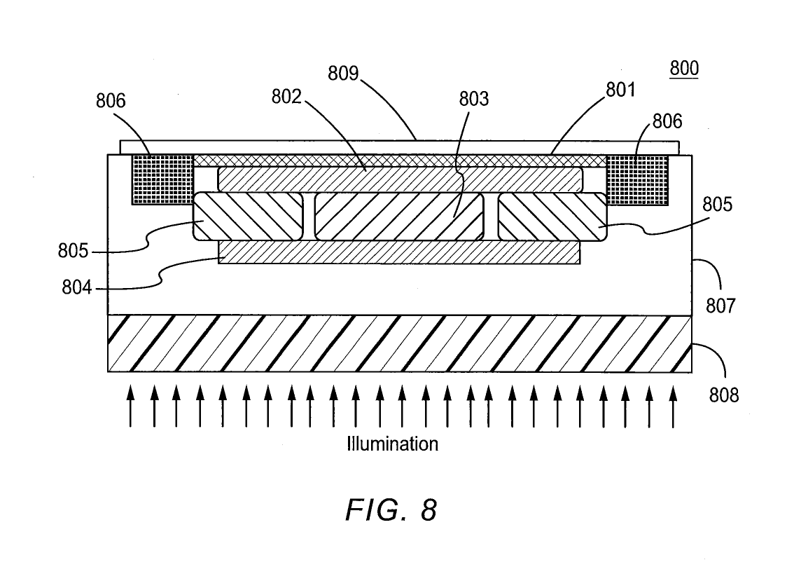

FIGS. 7-8 illustrate exemplary photodiodes 700, 800 in a back-side illumination configuration. Specifically, FIG. 7 illustrates a photodiode 700 which has a similar structure to photodiode 500 except that photodiode 700 is configured for back-side illumination; while FIG. 8 illustrates a photodiode 800 which has a similar structure to photodiode 600 except that photodiode 800 is configured for back-side illumination.

In FIG. 7, rather than including a substrate such as substrate 508, photodiode 700 includes a back-side dielectric 708 which acts as a light-receiving surface. Similarly, in FIG. 8, rather than including a substrate such as substrate 608, photodiode 800 includes a back-side dielectric 808 which acts as a light-receiving surface.

While FIGS. 7-8 illustrate particular implementations of respective photodiodes with a back-side illumination configuration, the present disclosure is not limited to the exact structure drawn. Other back-side illumination variations (for example, variations in sensor thickness, optical stack, etc.) will be readily understood by those with skill in the art.

Although the photodiode regions in the above preferred photodiodes are referred to as “implants,” this disclosure is not limited to regions formed by an implantation method. In various aspects of the present disclosure, the photodiode regions may be formed by epitaxial growth, ion implantation, dopant diffusion, or any other known method of forming a semiconductor p-n junction.

The deep photodiodes illustrated in FIGS. 5-8 not only have high sensitivity and high MTF for NIR illumination as compared to the comparative photodiode, but also have a sufficiently low pinning voltage for good pixel operation. This and other advantages are realized as a result of at least the reduced distance that carriers must diffuse to be collected by the photodiode, whereas the low pinning voltage is realized as a result of the deep depleting implant depleting the deep photodiode implant from multiple sides.

[Photodiode Manufacturing Process]

Preferably, the deep photodiode and depleting implants are performed early in the manufacturing process; that is, prior to the formation of the gate oxide. In this manner, the additional thermal budget helps deepen the photodiode implant, further improving MTF performance. Additionally, in this manner, implant defects can be better prevented and/or annealed out. Alternatively, either the deep photodiode and/or the deep depleting implants can be done after gate formation. In this manner, sharper p-n junctions may be realized; however, the implants may not diffuse as deeply, thereby producing less of a NIR improvement.

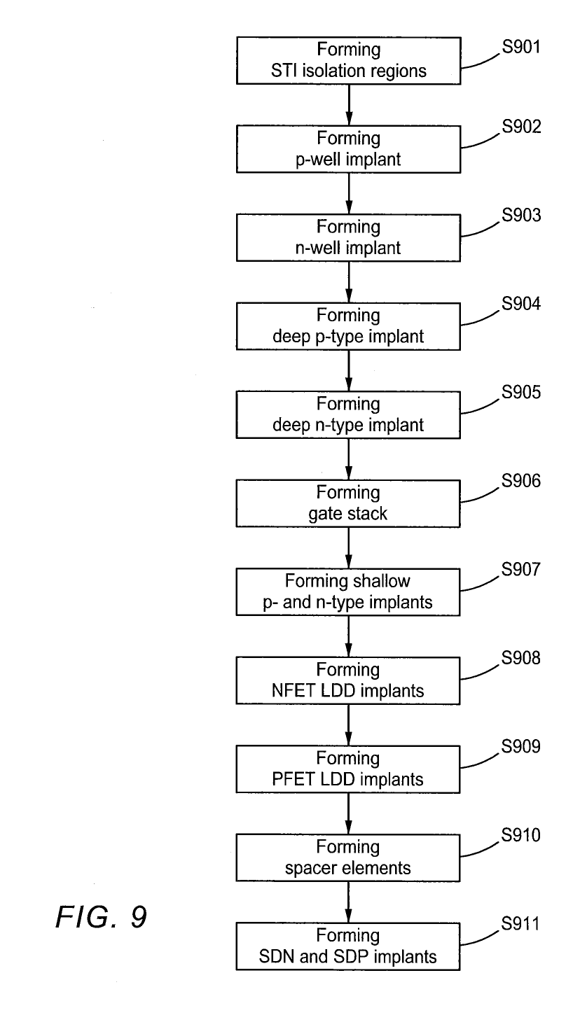

FIG. 9 illustrates an exemplary process flow for manufacturing an image sensor according to various aspects of the present disclosure.

At step S901, STI isolation regions are formed. At step S902, a p-well implant for photodiode isolation and/or well formation in the periphery is formed or provided. At step S903, an n-well implant (for example, for n-well formation in the periphery) is formed. At step S904, a deep p-type implant is formed (for example, a deep depleting implant). At step S905, a deep n-type implant is formed (for example, a deep photodiode implant or first and second deep photodiode implants). At step S906, a gate stack is formed (for example, including a gate oxide layer). At step S907, shallow p- and n-type implants are formed (for example, a shallow photodiode implant and a shallow depleting implant). At step S908, NFET lightly doped drain (LDD) implants are formed (for example, corresponding to NMOS transistors of transistors M1-M5). At step S909, PFET LDD implants are formed (for example, corresponding to PMOS transistors of transistors M1-M5). At step S910, spacer elements are formed. At step S911 n-type source/drain implants (SDN) and p-type source/drain implants (SDP) are formed (for example, corresponding to transistors M1-M5).

[Electronic Apparatus]

An electronic apparatus may be configured to include the image sensor 10 described above. For example, electronic apparatus may include digital cameras (including both cameras configured to take still images and those configured to take moving images), cellular phones, smartphones, tablet devices, personal digital assistants (PDAs), laptop computers, desktop computers, webcams, telescopes, sensors for scientific experiments, and any electronic apparatus for which it may be advantageous to detect light and/or capture images.

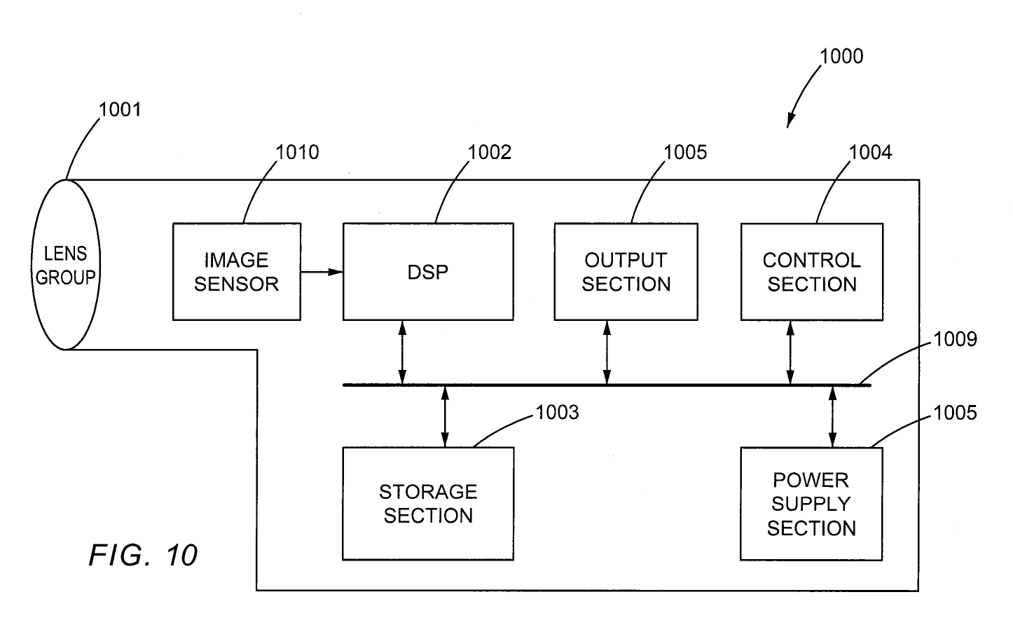

An exemplary electronic apparatus in the form of a digital camera is shown in FIG. 10 and described in more detail below. However, it will be understood by those in the art that the image sensor 10 could be provided in a different electronic apparatus that has features similar to the features of the camera shown in FIG. 10, and that the electronic apparatus may include additional features not shown in FIG. 10 and/or may omit certain features shown in FIG. 10 as appropriate.

FIG. 10 shows a camera 1000 comprising an optical system 1001 that is configured to direct light to the image sensor 1010. Image sensor 1010 is preferably an image sensor of the type described above with respect to FIGS. 1-3 and 5-8. In particular, optical system 1001 may preferably include an objective lens (not illustrated) that is configured to focus incident light at a focal point near the incident-light side of the image sensor 1010. The objective lens may comprise a single lens, a lens group, or multiple lens groups. For example, a zoom-lens may be provided in which multiple lens groups are movable with respect to one another in order to zoom in or out. Moreover, a focusing mechanism may be provided in order to provide focusing functionality to the camera, for example by moving the objective lens and/or the image sensor 1010 relative to one another.

Moreover, a digital signal processing section (DSP) 1002 may be provided to perform signal processing on signals received from the image sensor 1010 (for example, to receive signals from image sensor 1010 and output data); a storage section 1003 may be provided to store data generated by the image sensor 1010; a control section 1004 may be provided to control operations of the image sensor 1010; a power supply section 1005 may be provided to supply power to the image sensor 1010; and an output unit 1005 may be provided to output captured image data. Individual sections may be integrated with one or more other sections, or each individual section may be a separate integrated circuit. Individual sections may be connected to one another via a bus 1009, including a wired or wireless connection. Control section 1004 may include a processor that executes instructions stored on a non-transitory computer-readable medium, for example a memory included in storage section 1003. Output unit 1006 may be an interface for facilitating transmission of the stored data to external devices and/or for displaying the stored data as an image on a display device, which display device may be provided separate from or integral with the camera 1000.

Image sensor 1010 itself may include various sections therein for performing signal processing of the pixel signals generated by the pixel array, and/or signal processing sections may be provided in the electronic apparatus separate from image sensor 1010. Preferably, image sensor 1010 itself performs at least some signal processing functions, in particular A/D conversion and CDS noise cancellation. The electronic apparatus may also preferably perform some signal processing functions, for example converting the raw data from the image sensor 1010 into an image/video storage format (e.g., MPEG-4 or any known format), via the processor and/or via a dedicated signal processing section such as a video encoder/decoder unit.

In general, computing systems and/or devices, such as some of the above-described electronic apparatus, may employ any of a number of computer operating systems, including, but by no means limited to, versions and/or varieties of the Microsoft Windows® operating system, the Unix operating system (e.g., the Solaris® operating system distributed by Oracle Corporation of Redwood Shores, Calif.), the AIX UNIX operating system distributed by International Business Machines of Armonk, N.Y., the Linux operating system, the Mac OSX and iOS operating systems distributed by Apple Inc. of Cupertino, Calif., the BlackBerry OS distributed by Research In Motion of Waterloo, Canada, and the Android operating system developed by the Open Handset Alliance.

Computing devices generally include computer-executable instructions, where the instructions may be executable by one or more computing devices such as those listed above. Computer-executable instructions may be compiled or interpreted from computer programs created using a variety of programming languages and/or technologies, including, without limitation, and either alone or in combination, Java™, C, C++, C#, Objective C, Visual Basic, Java Script, Perl, etc. In general, a processor (e.g., a microprocessor) receives instructions, e.g., from a memory, a computer-readable medium, etc., and executes these instructions, thereby performing one or more processes, including one or more of the processes described herein. Such instructions and other data may be stored and transmitted using a variety of computer-readable media.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Non-volatile media may include, for example, optical or magnetic disks and other persistent memory. Volatile media may include, for example, dynamic random access memory (DRAM), which typically constitutes a main memory. Such instructions may be transmitted by one or more transmission media, including coaxial cables, copper wire and fiber optics, including the wires that comprise a system bus coupled to a processor of a computer. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, or any other medium from which a computer can read.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

1. An image sensing device comprising:
a photodiode region of a first dopant type, the photodiode region including a shallow photodiode region and a first deep photodiode region, wherein a length of the shallow photodiode region is larger than a length of the first deep photodiode region; and
a depleting region of a second dopant type, the depleting region including a shallow depleting region and a deep depleting region, wherein the deep depleting region surrounds the first deep photodiode region on at least two opposite sides,
wherein the second dopant type is of opposite dopant type to the first dopant type.

2. The image sensing device according to claim 1, wherein the entire photodiode region is configured to be fully depleted of carriers during a photodiode reset.

3. The image sensing device according to claim 1, wherein a depth of the first deep photodiode region is substantially equal to a depth of the deep depleting region.

4. The image sensing device according to claim 1, wherein the photodiode region further includes a second deep photodiode region, wherein a length of the second deep photodiode region is larger than the length of the first deep photodiode region.

5. The image sensing device according to claim 4, wherein the second deep photodiode region is deeper than the deep depleting region.

6. The image sensing device according to claim 1, further comprising a gate oxide layer.

7. The image sensing device according to claim 6, wherein the first deep photodiode region and the deep depleting region are formed before the gate oxide layer.

8. The image sensing device according to claim 6, wherein the photodiode region is formed before the gate oxide layer, and the depleting region is formed after the gate oxide layer.

9. The image sensing device according to claim 6, wherein the depleting region is formed before the gate oxide layer, and the photodiode region is formed after the gate oxide layer.

10. The image sensing device according to claim 1, wherein the image sensing device is configured as a back-side illumination type image sensing device.

11. An electronic apparatus comprising:
an optical system;
an image sensing device configured to receive incident light from the optical system, wherein the image sensing device is an image sensing device according to claim 1; and
a signal processor configured to receive signals from the image sensing device and output data.

12. A method of manufacturing an image sensing device comprising:
forming a photodiode region of a first dopant type, the photodiode region including a shallow photodiode region and a first deep photodiode region, wherein a length of the shallow photodiode region is larger than a length of the first deep photodiode region; and
forming a depleting region of a second dopant type, the depleting region including a shallow depleting region and a deep depleting region, wherein the deep depleting region surrounds the first deep photodiode region on at least two opposite sides,
wherein the second dopant type is of opposite dopant type to the first dopant type.

13. The method of manufacturing an image sensing device according to claim 12, wherein the entire photodiode region is configured to be fully depleted of carriers during a photodiode reset.

14. The method of manufacturing an image sensing device according to claim 12, wherein a depth of the first deep photodiode region is substantially equal to a depth of the deep depleting region.

15. The method of manufacturing an image sensing device according to claim 12, wherein the photodiode region further includes a second deep photodiode region, wherein a length of the second deep photodiode region is larger than the length of the first deep photodiode region.

16. The method of manufacturing an image sensing device according to claim 15, wherein the second deep photodiode region is deeper than the deep depleting region.

17. The method of manufacturing an image sensing device according to claim 12, further comprising forming a gate oxide layer.

18. The method of manufacturing an image sensing device according to claim 17, further comprising forming the first deep photodiode region and the deep depleting region before forming the gate oxide layer.

19. The method of manufacturing an image sensing device according to claim 17, further comprising forming the photodiode region before forming the gate oxide layer, and forming the depleting region after forming the gate oxide layer.

20. The method of manufacturing an image sensing device according to claim 17, further comprising forming the depleting region before forming the gate oxide layer, and forming the photodiode region after forming the gate oxide layer.

21. The method of manufacturing an image sensing device according to claim 12, wherein the image sensing device is configured as a back-side illumination type image sensing device.
